(19) United States
(12) Patent Application Publication
(10) Pub. No.: US 2024/0120327 A1
(43) Pub. Date: Apr. 11, 2024

(54) SOLID-STATE LIGHT-EMITTING DEVICE AND PRODUCTION METHOD THEREOF, AND DISPLAY DEVICE

(71) Applicant: Xiamen Extremely PQ Display Technology Co., Ltd., Xiamen (CN)

(72) Inventor: XIANGWEI XIE, Xiamen (CN)

(21) Appl. No.: 18/391,852

(22) Filed: Dec. 21, 2023

Related U.S. Application Data
(63) Continuation of application No. PCT/CN2021/134061, filed on Nov. 29, 2021.

(51) Int. Cl. H01L 25/16; H01L 33/62

(52) U.S. Cl. CPC H01L 25/167; H01L 33/62; H01L 2933/0066

(57) ABSTRACT

A solid-state light-emitting device and a production method thereof, and a display device are provided. The solid-state light-emitting device includes multiple light-emitting components sequentially stacked in a vertical direction and connected in series to form a stacked light-emitting structure. Each light-emitting component includes a first electrode, a second electrode, a first semiconductor layer, a source layer and a second semiconductor layer, and the first semiconductor layer, the source layer and the second semiconductor layer are sequentially stacked between the first electrode and the second electrode in the vertical direction. In addition, the first electrode of one of every adjacent two light-emitting components is bonded to the second electrode of the other of the adjacent two light-emitting components in the vertical direction to form an electrical connection.

### CROSS-REFERENCE TO RELATED APPLICATION

This application is a continuation of International Application No. PCT/CN2021/134061, filed on Nov. 29, 2021. The international Application claims priority from Chinese patent application No. 202111435195.9, filed on Nov. 29, 2021. The entire contents of the above-mentioned applications are hereby incorporated herein by reference.

### TECHNICAL FIELD

The disclosure relates to the field of luminescence and display technologies, and particularly to a solid-state light-emitting device and a production method thereof, and a display device.

### BACKGROUND

A micro light-emitting diode (micro-LED) chip typically refer to a semiconductor light-emitting diode (LED) chip with a length, a width, and a thickness less than 100 microns (m), and with a growth substrate removed. The micro-LED chip usually includes one PN structure, which means that a commonly used structure of the micro-LED chip is a single PN structure. The micro-LED chip is a current-mode device that requires a large driving current (also known as working current) in micro-LED display devices, which results in high heating and power consumption of circuits. Therefore, how to reduce the driving current of the micro-LED chip while maintaining brightness to reduce power consumption is currently a technical problem that needs to be solved.

### SUMMARY

Therefore, in order to overcome at least some of the defects and deficiencies of the related art, embodiments of the disclosure provide a solid-state light-emitting device and a production method thereof, and a display device.

Specifically, in an aspect, an embodiment of the disclosure provides a solid-state light-emitting device, for example including: multiple light-emitting components, and the multiple light-emitting components are sequentially stacked in a vertical direction and connected in series to form a stacked light-emitting structure. Each light-emitting component includes a first electrode, a second electrode, a first semiconductor layer, a source layer and a second semiconductor layer, and the first semiconductor layer, the source layer and the second semiconductor layer are sequentially stacked between the first electrode and the second electrode in the vertical direction. In addition, the first electrode of one of every adjacent two light-emitting components of the multiple light-emitting components is bonded to the second electrode of the other of the adjacent two light-emitting components in the vertical direction to form an electrical connection of the adjacent two light-emitting components.

In an embodiment, the first electrode of the light-emitting component disposed at a bottom of the stacked light-emitting structure in the vertical direction includes a planar metal electrode, and the second electrode of the light-emitting component disposed at a top of the stacked light-emitting structure in the vertical direction includes multiple punctate electrodes or multiple strip-shaped electrodes.

In an embodiment, the first electrode of the light-emitting component disposed at a bottom of the stacked light-emitting structure in the vertical direction includes a planar metal electrode, and the second electrode of the light-emitting component disposed at a top of the stacked light-emitting structure in the vertical direction includes a planar transparent electrode.

In an embodiment, shapes of the bonded first and second electrodes are the same, and each of the bonded first and second electrodes includes multiple punctate electrodes or multiple strip-shaped electrodes.

In an embodiment, each of the bonded first and second electrodes includes a strip-shaped electrode group, and the strip-shaped electrode group of the first electrode is perpendicular with the strip-shaped electrode group of the second electrode to form a vertical grid connection of the bonded first and second electrodes.

In an embodiment, a gap is defined between every adjacent two light-emitting components due to thicknesses of the first electrode and the second electrode, and a transparent material is filled in the gap.

In an embodiment, the multiple light-emitting components are multiple light-emitting components with same colors.

In an embodiment, the multiple light-emitting components are multiple light-emitting components with different colors.

In an embodiment, each light-emitting component is a micro-LED chip, the source layer is a multi-quantum well layer, and a length, a width, and a height of the micro-LED chip are all less than 100 μm.

In another aspect, an embodiment of the disclosure provides a display device, for example including a driving substrate and multiple display pixels disposed on the driving substrate and electrically connected to the driving substrate. Each display pixel includes multiple sub-pixels with different colors, and each sub-pixel utilizes the solid-state light-emitting device mentioned above.

In an embodiment, the driving substrate is a passive matrix driving substrate or an active matrix driving substrate.

In another aspect, an embodiment of the disclosure provides a production method of a solid-state light-emitting device, for example including the following steps:
multiple first light-emitting components spaced apart from each other and disposed on a transition carrier plate are provided; each first light-emitting component includes a first electrode, a second electrode, a first semiconductor layer, a source layer and a second semiconductor layer; the first semiconductor layer, the source layer and the second semiconductor layer are sequentially stacked between the first electrode and the second electrode in the vertical direction, the first electrode is disposed on a side of the first semiconductor layer facing away from the source layer, and the second electrode is disposed on a side of the second semiconductor layer facing away from the source layer;
multiple light-emitting structures spaced apart from each other and disposed on a growth substrate are provided; each light-emitting structure includes a third electrode, a third semiconductor layer, a second source layer and a fourth semiconductor layer sequentially stacked in that order, and the growth substrate is disposed on a side of the fourth semiconductor layer facing away from the second source layer;
the third electrodes of the multiple light-emitting structures are bonded with second electrodes of the multiple first light-emitting components by utilizing a face-to-face bonding to obtain multiple stacked structures spaced apart from each other and disposed between the transition carrier plate and the growth substrate, each stacked structure includes a corresponding one of the multiple first light-emitting components and a corresponding one of the multiple light-emitting structures;
the growth substrate is removed to expose the multiple stacked structures spaced apart from each other; and
a fourth electrode is provided on the side of the fourth semiconductor layer facing away from the second source layer of each stacked structure after the exposing to obtain multiple stacked light-emitting structures spaced apart from each other and disposed on the transition carrier plate, thereby forming multiple stacked light-emitting devices spaced apart from each other and disposed on the transition carrier plate; each stacked light-emitting structure includes a corresponding one of the first light-emitting components, and a second light-emitting component; and each second light-emitting component includes a corresponding one of the light-emitting structures, and the fourth electrode.

In an embodiment, the face-to-face bonding is utilized a metal bonding process.

In an embodiment, a shape of the third electrode is consistent with a shape of the second electrode, and the third electrode and the second electrode each include multiple punctate electrodes or multiple strip-shaped electrodes.

In an embodiment, each of the third electrode and the second electrode includes a strip-shaped electrode group, and the strip-shaped electrode group of the third electrode is perpendicular with the strip-shaped electrode group of the second electrode to form a vertical grid connection.

In an embodiment, the first light-emitting component and the second light-emitting component of each stacked light-emitting structure are light-emitting components with same colors.

In an embodiment, the first light-emitting component and the second light-emitting component of each stacked light-emitting structure are light-emitting components with different colors.

As described above, the embodiment of the disclosure provides the solid-state light-emitting device with stacked structures in series, which can reduce the driving current while maintaining the luminous brightness, thereby reducing power consumption. In addition, when the light-emitting component is micro-LED and applied to passive matrix display devices (or passive drive display devices) or active matrix display devices (or active drive display devices), a stacked series structure is formed in advance, so that the difficulty of massive transfer will not be increased, and the goal of reducing power consumption can be achieved. Moreover, due to a stacked arrangement of light-emitting components in the vertical direction, the stacked arrangement does not increase the occupied space on the driving substrate, which means that the stacked arrangement does not reduce the resolution, i.e., pixels per inch (PPI).

### BRIEF DESCRIPTION OF DRAWINGS

In order to more clearly illustrate technical solutions of embodiments of the disclosure, the accompanying drawings used in the description of the embodiments will be briefly introduced below. Apparently, the accompanying drawings in the following description are only some of the embodiments of the present disclosure, and those skilled in the art can obtain other drawings according to these drawings without creative effort.

FIG. 1A illustrates a structural schematic diagram of a solid-state light-emitting device in an embodiment 1 of the disclosure.

FIG. 1B illustrates a schematic circuit diagram of the solid-state light-emitting device shown in FIG. 1A.

FIGS. 2A to 2F illustrate schematic diagrams of shapes and connection relationships between a first electrode and a second electrode bonded to each other in the embodiment 1 of the disclosure.

FIG. 3A illustrates a schematic diagram of a passive matrix display device applied with the solid-state light-emitting device in FIG. 1A.

FIG. 3B illustrates an equivalent circuit diagram of a single sub-pixel in FIG. 3A.

FIG. 4A illustrates a schematic diagram of an active matrix display device applied with the solid-state light-emitting device in FIG. 1A.

FIG. 4B illustrates an equivalent circuit diagram of a single sub-pixel in FIG. 4A.

FIGS. 5A to 5E illustrate schematic diagrams of related structures of multiple steps in a production method of the solid-state light-emitting device in FIG. 1A.

FIG. 6 illustrates a structural schematic diagram of another solid-state light-emitting device in the embodiment 1 of the disclosure.

FIG. 7 illustrates a structural schematic diagram of still another solid-state light-emitting device in the embodiment 1 of the disclosure.

FIG. 8 illustrates a structural schematic diagram of a display device in an embodiment 2 of the disclosure.

### DETAILED DESCRIPTION OF EMBODIMENTS

In order to make the purposes, technical solutions, and advantages of the embodiments of the disclosure clearer, the following will provide a clear and complete description of the technical solutions in the embodiments of the disclosure in conjunction with the attached drawings. Apparently, the described embodiments are only some of the embodiments of the disclosure, not all of the embodiments. Based on the embodiments described in the disclosure, all other embodiments obtained by those skilled in the art without creative labor belong to the scope of protection of the disclosure.

It should be noted that all directional indications (such as up, down, left, right, front, back, top, bottom) are only used to explain the relative position relationship, motion situation, etc. between components in a specific posture (as shown in the attached drawings) in the embodiments of the disclosure. If the specific posture changes, the directional indication also changes accordingly. In addition, the term “vertical” in the embodiments and claims of the disclosure refers to an angle of 90° or a deviation of −5° to +5° between two components, while the term “parallel” refers to an angle of 0° or a deviation of −5° to +5° between two components.

In the embodiments of the disclosure, descriptions involving “first” and “second” are only used for descriptive purposes and cannot be understood as indicating or implying their relative importance or implying the number of indicated technical features. Therefore, features limited to “first” and “second” can explicitly or implicitly include at least one of these features.

### Embodiment 1

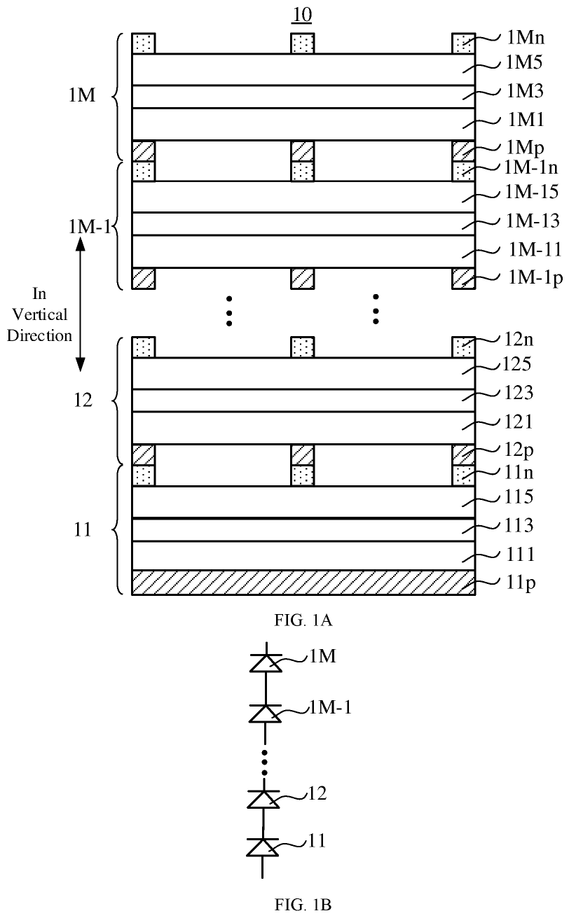

As shown in FIG. 1A and FIG. 1B, the embodiment 1 of the disclosure provides a solid-state light-emitting device 10, including multiple light-emitting components 11, 12, 1M-1 and 1M. The multiple light-emitting components 11, 12, 1M-1 and 1M are sequentially stacked in a vertical direction and connected in series to form a stacked light-emitting structure. FIG. 1B illustrates a schematic circuit diagram of the solid-state light-emitting device 10, and the multiple light-emitting components 11, 12, 1M-1 and 1M are sequentially connected in series. It should be noted that a number of the light-emitting components of the solid-state light-emitting device 10 is not limited to the number shown in FIG. 1A, but can be other numbers, such as two, three, or more, that is, M≥2.

The light-emitting component 11 includes a first electrode 11p such as a p electrode, a second electrode 11n such as an n electrode, a first semiconductor layer 111 such as an n-type semiconductor layer, a source layer 113 such as a multiple quantum well layer and a second semiconductor layer 115 such as a p-type semiconductor layer; and the first semiconductor layer 111, the source layer 113 and the second semiconductor layer 115 are sequentially stacked between the first electrode 11p and the second electrode 11n in the vertical direction.

Analogously, the light-emitting component 12 includes a first electrode 12p such as a p electrode, a second electrode 12n such as an n electrode, a first semiconductor layer 121 such as an n-type semiconductor layer, a source layer 123 such as a multiple quantum well layer and a second semiconductor layer 125 such as a p-type semiconductor layer; and the first semiconductor layer 121, the source layer 123 and the second semiconductor layer 125 are sequentially stacked between the first electrode 12p and the second electrode 12n in the vertical direction.

Analogously, the light-emitting component 1M-1 includes a first electrode 1M-1p such as a p electrode, a second electrode 1M-1n such as an n electrode, a first semiconductor layer 1M-11 such as an n-type semiconductor layer, a source layer 1M-13 such as a multiple quantum well layer and a second semiconductor layer 1M-15 such as a p-type semiconductor layer; and the first semiconductor layer 1M-11, the source layer 1M-13 and the second semiconductor layer 1M-15 are sequentially stacked between the first electrode 1M-1p and the second electrode 1M-1n in the vertical direction.

Analogously, the light-emitting component 1M includes a first electrode 1Mp such as a p electrode, a second electrode 1Mn such as an n electrode, a first semiconductor layer 1M1 such as a n-type semiconductor layer, a source layer 1M3 such as a multiple quantum well layer and a second semiconductor layer 1M5 such as p-type semiconductor layer; and the first semiconductor layer 1M1, the source layer 1M3 and the second semiconductor layer 1M5 are sequentially stacked between the first electrode 1Mp and the second electrode 1Mn in the vertical direction.

In addition, in the vertical direction, the light-emitting component 11 and the light-emitting component 12 are adjacent two light-emitting components, and the light-emitting component 1M-1 and the light-emitting component 1M are adjacent two light-emitting components. For the light-emitting component 11 and the light-emitting component 12, the first electrode 12p of the light-emitting component 12 and the second electrode 11n of the light-emitting component 11 are bonded to form an electrical connection, and for the light-emitting component 1M-1 and the light-emitting component 1M, the first electrode 1Mp of the light-emitting component 1M and the second electrode 1M-in of the light-emitting component 1M-1 are bonded to form an electrical connection. In short, in the stacked light-emitting structure, the first electrode of one of every adjacent two light-emitting components is bonded to the second electrode of the other of the adjacent two light-emitting components to form the electrical connection. A bonding process utilized to bond in the embodiment may be a metal bonding process. For example, the first electrode and the second electrode are bonded through a pure tin (Sn) layer, a gold tin (Sn/Au) layer, a titanium copper (Ti/Cu) layer, or an aluminum nickel gold (Al/Ni/Au) layer under heating and pressure conditions. Certainly, other bonding connection methods can also be used between the electrodes of every adjacent two light-emitting components, as long as there is a transparent area in the middle of the light-emitting unit and the light from the light-emitting component at the bottom is not completely blocked.

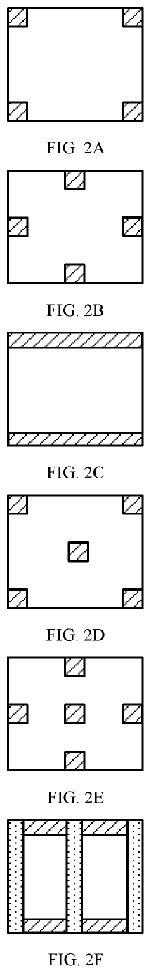

In the embodiment, the electrode connection between every adjacent two light-emitting components can be bonded in a limited area at four corners or edges of the light-emitting components. As shown in FIG. 2A to FIG. 2E, each first electrode includes multiple punctate electrodes or multiple strip-shaped electrodes, and the shapes of the bonded first and second electrodes are the same, that is, the second electrode bonded to the first electrode includes multiple punctate electrodes or multiple strip-shaped electrodes. Moreover, the electrode connection between every adjacent two light-emitting components can also utilize a vertical grid connection, as shown in FIG. 2F, the first electrode and the second electrode are strip electrodes perpendicular to each other.

As shown in FIG. 1A, in the vertical direction, the first electrode lip of the light-emitting component 11 disposed at a bottom of the stacked light-emitting structure includes a planar metal electrode, and the second electrode 1Mn of the light-emitting component 1M disposed at a top of the stacked light-emitting structure includes multiple punctate electrode or multiple strip-shaped electrode.

Furthermore, it is worth noting that the light-emitting components 11, 12, 1M-1 and 1M of the stacked light-emitting structure of the solid-state light-emitting device 10 can be multiple light-emitting components with same colors, such as all red light-emitting components, all blue light-emitting components, all green light-emitting components, or other light-emitting components with the same colors, thereby forming a monochromatic series high-voltage light-emitting device as a whole. Certainly, in other embodiments of the disclosure, the light-emitting components 11, 12, 1M-1 and 1M of the stacked light-emitting structure of the solid-state light-emitting device 10 can be multiple light-emitting components with different colors, such as a mixture of the red light-emitting component, the green light-emitting component, and the blue light-emitting component, which can generate multi-spectral light with red, green, and blue colors, thereby forming a multi-color series high-voltage light-emitting device as a whole.

In addition, in a preferred embodiment of the disclosure, the light-emitting components 11, 12, 1M-1 and 1M are all micro-LED chips, all the source layers 113, 123, 1M-13 and 1M3 are multi-quantum well layers, and lengths, widths, and heights of the micro light-emitting diode chips are all less than 100 μm.

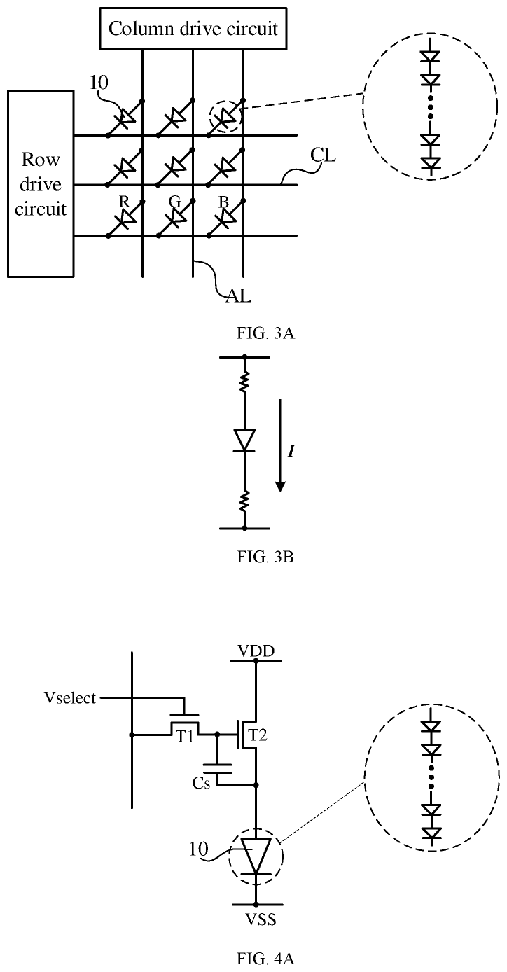

As shown in FIG. 3A and FIG. 3B, the solid-state light-emitting device 10 can be applied to a passive matrix display device. Specifically, as shown in FIG. 3A, nine solid-state light-emitting devices 10 are disposed in a 3×3 array and electrically connecting three anode lines AL and three cathode lines CL, and the nine solid-state light-emitting devices 10 are controlled by a column drive circuit and a row drive circuit to realize an image display. As shown in FIG. 3A, it is worth noting that the nine solid-state light-emitting devices 10 respectively form nine sub-pixels to obtain three red sub-pixels R, three green sub-pixels G, and three blue sub-pixels B. Furthermore, as shown in FIG. 3B, due to a line impedance, a single sub-pixel of the passive matrix display device can be equivalent to a series connection between the solid-state light-emitting device and the line impedance. Due to the series connection of the M numbers of light-emitting components of the solid-state light-emitting device 10 to emit light, the driving current of the solid-state light-emitting device 10 can be significantly reduced (theoretically, the driving current of the solid-state light-emitting device 10 is 1/M of the driving current of the solid-state light-emitting device with a single PN structure) in order to achieve the same brightness. In addition, a turn-on voltage Vf of the solid-state light-emitting device 10 of this embodiment is also increased to the sum of the turn-on voltages Vf of the multiple light-emitting components. Although the overall driving voltage increases, the increased voltage is applied to the light-emitting components 11, 12, 1M-1 and 1M of the solid-state light-emitting device 10, thereby improving the utilization of effective power consumption.

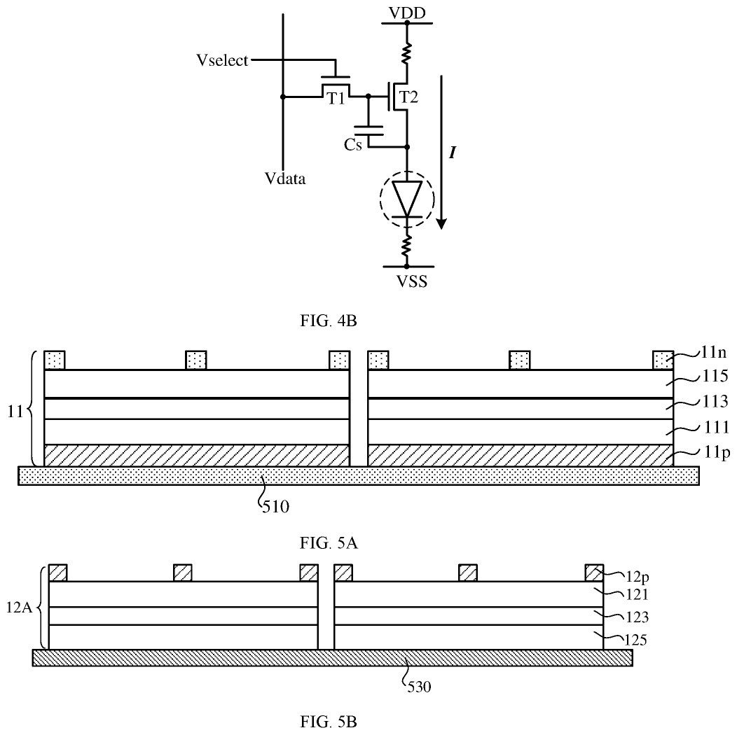

As shown in FIG. 4A and FIG. 4B, the solid-state light-emitting device 10 can be applied to an active matrix (AM) display device. Specifically, as shown in FIG. 4A, which illustrates a circuit structure of a single sub-pixel, specifically including a selecting transistor T1, a driving transistor T2, a storage capacitor Cs, and the solid-state light-emitting device 10 that are electrically connected to each other. When a scanning signal V_{select} on a scanning line is input, the selecting transistor T1 is turned on, and a data signal Vdata on a data line is transmitted to a grid of the driving transistor T2, while charging the storage capacitor Cs. Then the driving transistor T2 is turned on to make a driving current to pass between a supply voltage VDD and a reference voltage VSS. The driving current flows through the solid-state light-emitting device 10, which emits light under the action of the driving current. Due to a holding effect of the storage capacitor Cs, the grid voltage of the driving transistor T2 remains unchanged throughout the entire display time period, resulting in the unchanged turn-on state of the driving transistor T2 throughout the entire display time period. A stable driving current can flow from the supply voltage VDD to the solid-state light-emitting device 10 to the reference voltage VSS throughout the entire display time period, thereby ensuring that the solid-state light-emitting device 10 can emit light normally throughout the entire display time period. In addition, as shown in FIG. 4B, due to the line impedance and a transistor impedance, the single sub-pixel of the active matrix display device can be equivalent to a series connection of the solid-state light-emitting device, the line impedance and the transistor impedance. Due to the series connection of the M numbers of light-emitting components of the solid-state light-emitting device 10 to emit light, the series connection can significantly reduce the driving current of the solid-state light-emitting device 10 (theoretically, the driving current of the solid-state light-emitting device 10 is 1/M of the driving current of a solid-state light-emitting device with a single PN structure) in order to achieve the same brightness. In addition, a turn-on voltage Vf of the solid-state light-emitting device 10 of this embodiment is also increased to the sum of the turn-on voltages Vf of the multiple light-emitting components. Although the overall driving voltage increases, the increased voltage is applied to the light-emitting components 11, 12, 1M-1 and 1M of the solid-state light-emitting device 10, thereby improving the utilization of effective power consumption.

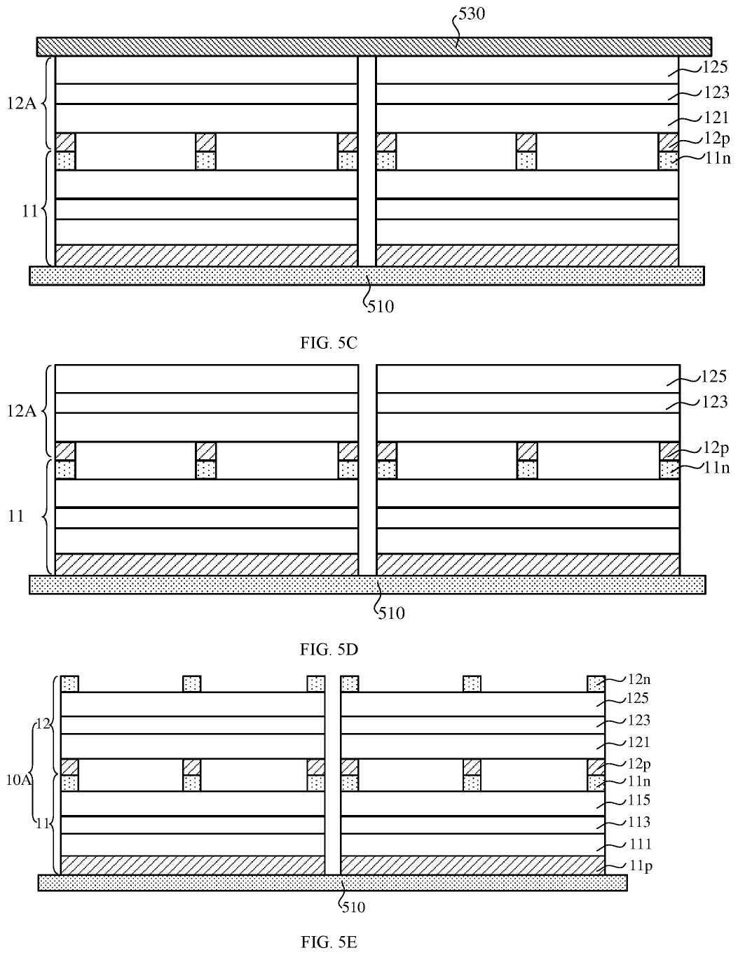

To facilitate a clearer understanding of the solid-state light-emitting device 10 of the embodiment, a production method of the solid-state light-emitting device 10 is briefly described with reference to FIGS. 5A-5E, and the light-emitting components 11, 12, 1M-1 and 1M are taken as the micro-LED chips as an example. The steps of the production method are as follows.
Step (1): as shown in FIG. 5A, multiple light-emitting components 11 spaced apart from each other and disposed on a transition carrier plate 510 are provided. Each light-emitting component 11 includes a first electrode 11p, a second electrode 11n, a first semiconductor layer 111, a source layer 113 and a second semiconductor layer 115. The first semiconductor layer 111, the source layer 113 and the second semiconductor layer 115 are sequentially stacked in that order between the first electrode 11p and the second electrode 11n in the vertical direction, the first electrode 11p is disposed on a side of the first semiconductor layer 11I facing away from the source layer 113, and the second electrode 11n is disposed on a side of the second semiconductor layer 115 facing away from the source layer 113. More specifically, after providing the first electrodes lip on epitaxial wafers where the multiple light-emitting components 11 are located, a first layer of micro-LED grains is etched and temporarily bonded to the transition carrier plate 510 (such as a sapphire substrate). Then, when the epitaxial wafers are blue LED epitaxial wafers or green LED epitaxial wafers, a growth substrate such as the sapphire substrate can be removed using a laser lift-off (LLO) method, when the epitaxial wafers are red LED epitaxial wafers, the growth substrate such as a GaAs substrate can be removed using chemical etching method. In addition, after removing the growth substrate, the second electrodes 11n are provided, thereby obtaining the structure as shown in FIG. 5A.
Step (2): as shown in FIG. 5B, multiple light-emitting structures 12A spaced apart from each other and disposed on the growth substrate 530 are provided. Each light-emitting structure 12A includes a first electrode 12p, a first semiconductor layer 121, a source layer 123 and a second semiconductor layer 125 sequentially stacked in that order, and the growth substrate 530 is disposed on a side of the second semiconductor layer 125 facing away from the source layer 123. More specifically, after providing the first electrodes 12p with the structures (refer to FIGS. 2A to 2F) corresponding to the second electrodes 11n of the light-emitting components 11 in FIG. 5A on the epitaxial wafers where the multiple light-emitting structures 12A are located, and a second layer of micro-LED grains with a grain size equal to that of the first layer of micro-LED grains is etched, thereby obtaining the structure as shown in FIG. 5B.
Step (3): as shown in FIG. 5C, the first electrodes 12p of the multiple light-emitting structures 12A are respectively bonded with the second electrodes 11n of the multiple light-emitting components 11 by utilizing a face-to-face bonding to obtain multiple stacked structures spaced apart from each other and disposed between the transition carrier plate 510 and the growth substrate 530, and each stacked structure includes a corresponding one of the multiple light-emitting components 11 and a corresponding one of the multiple light-emitting structures 12A. The face-to-face bonding is utilized a metal bonding process, but the embodiments of the disclosure are not limited to this.
Step (4): the growth substrate 530 is removed to expose the multiple stacked structures spaced apart from each other, thereby obtaining the structure as shown in FIG. 5D.
Step (5): a second electrode 12n is provided on the side of the second semiconductor layer 125 facing away from the source layer 123 of each stacked structure after step (4) to obtain multiple stacked light-emitting structures 10A spaced apart from each other and disposed on the transition carrier plate 510 as shown in FIG. 5E, thereby forming multiple stacked light-emitting devices 10 spaced apart from each other and disposed on the transition carrier plate 510 (corresponding to M=2). Each stacked light-emitting structure 10A includes a corresponding one of multiple light-emitting components 11, and a light-emitting component 12, and the light-emitting component 12 includes a corresponding one of multiple light-emitting structures 12A, and the second electrode 12n. It is worth noting that when the solid-state light-emitting device 10 includes stacked light-emitting structure of three or more layers (corresponding to M≥3), steps (2) to (5) can be repeated one or more times to obtain required solid-state light-emitting device.

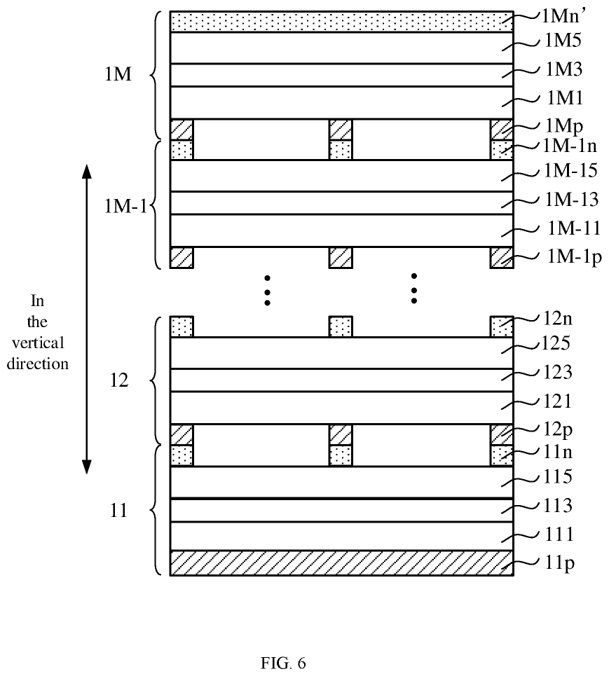

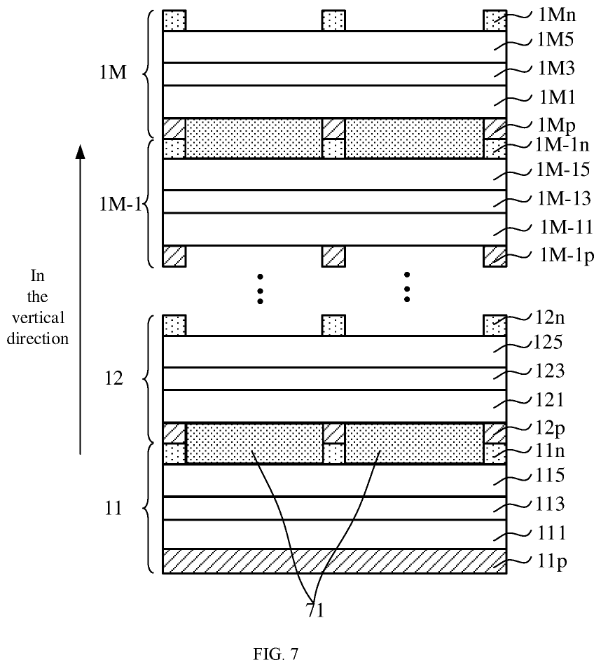

In addition, it is worth noting that the second electrode 1Mn of the topmost light-emitting component 1M in the stacked light-emitting structure of the solid-state light-emitting device 10 of this embodiment is not limited to the multiple punctate electrodes or the multiple strip-shaped electrodes as shown in FIG. 1A, but can also be the planar transparent electrode 1Mn′ as shown in FIG. 6. Furthermore, as shown in FIG. 7, a gap is defined between every adjacent two light-emitting components of the light-emitting components 11, 12, 1M-1 and 1M due to thicknesses of the first electrode and the second electrode, and a transparent material 71 is filled in the gap, thereby improving a light-emitting efficiency of the entire solid-state light-emitting device 10. The transparent material 71 can be an inorganic material such as silicon oxide, silicon nitride and silicon oxynitride, or an organic material such as polymethyl methacrylate (PMMA) or polycarbonate (PC). It is preferred to choose the transparent material with a refractive index of around 1.5, such as a refractive index range of 1.4 to 1.6.

### Embodiment 2

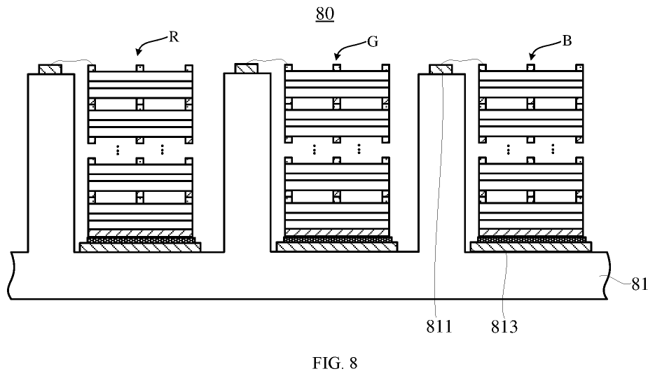

FIG. 8 illustrates a structural schematic diagram of a display device in the embodiment 2. As shown in FIG. 8, the display panel 80 includes a driving substrate 81 and multiple display pixels disposed on the driving substrate 81 and electrically connected to the driving substrate 81. For example, a single display pixel is shown as an example in FIG. 8, specifically, the single display pixel includes the multiple sub-pixels with different colors, such as a red sub-pixel R, a green sub-pixel G, and a blue sub-pixel B, and each sub-pixel uses any solid-state light-emitting device 10 as described in the embodiment 1. The driving substrate 81 can be a passive matrix driving substrate or an active matrix driving substrate.

More specifically, the driving substrate 81 is provided with multiple electrode structures (FIG. 8 only shows three electrode structures as an example), and each electrode structure includes a pair of electrodes 811 and 813. The solid-state light-emitting device in each of the red sub-pixel R, the green sub-pixel G, and the blue sub-pixel B is disposed on the driving substrate 81 and electrically connected to the electrodes 811 and 813 in the corresponding electrode structure.

From the above, it can be seen that the display device 80 of the embodiment uses a monochromatic series high-voltage light-emitting device, such as a monochromatic series high-voltage micro-LED chip, as its single sub-pixel. Compared to the related art that uses the micro-LED chip with a single PN structure as the sub-pixel, the display device 80 of the embodiment can reduce the driving current while maintaining a certain brightness, and thus the power consumption of the display device is reduced. In addition, during the production process of the display device 80, the solid-state light-emitting device 10 is a stacked series structure formed in advance, therefore, the difficulty of the massive transfer will not be increased. Furthermore, since the light-emitting components in the solid-state light-emitting device 10 are sequentially stacked in the vertical direction, the occupied space on the driving substrate 81 will not be increased, and the resolution, i.e., PPI will not be reduced.

Furthermore, it can be understood that the embodiments are only exemplary illustrations of the disclosure. On the premise that the technical features do not conflict, the structures are not contradictory, and the purposes of the disclosure are not violated, the technical solutions of various embodiments can be arbitrarily combined and used in combination.

Finally, it should be noted that the embodiments are only used to illustrate the technical solutions of the disclosure, not to limit the disclosure. Although the disclosure has been described in detail with reference to the embodiments, those skilled in the art should understand that they can still modify the technical solutions recorded in the embodiments or equivalently replace some of the technical features. And these modifications or replacements do not separate the essence of the corresponding technical solutions from the spirit and scope of the various embodiments of the disclosure.

What is claimed is:

1. A solid-state light-emitting device comprising:
a plurality of light-emitting components, sequentially stacked in a vertical direction and connected in series to form a stacked light-emitting structure;
wherein each light-emitting component comprises a first electrode, a second electrode, a first semiconductor layer, a source layer and a second semiconductor layer, and the first semiconductor layer, the source layer and the second semiconductor layer are sequentially stacked between the first electrode and the second electrode in the vertical direction; and
wherein the first electrode of one of every adjacent two light-emitting components of the plurality of light-emitting components is bonded to the second electrode of the other of the adjacent two light-emitting components in the vertical direction to form an electrical connection of the adjacent two light-emitting components.

2. The solid-state light-emitting device as claimed in claim 1, wherein the first electrode of the light-emitting component disposed at a bottom of the stacked light-emitting structure in the vertical direction comprises a planar metal electrode, and the second electrode of the light-emitting component disposed at a top of the stacked light-emitting structure in the vertical direction comprises a plurality of punctate electrodes or a plurality of strip-shaped electrodes.

3. The solid-state light-emitting device as claimed in claim 1, wherein the first electrode of the light-emitting component disposed at a bottom of the stacked light-emitting structure in the vertical direction comprises a planar metal electrode, and the second electrode of the light-emitting component disposed at a top of the stacked light-emitting structure in the vertical direction comprises a planar transparent electrode.

4. The solid-state light-emitting device as claimed in claim 1, wherein shapes of the bonded first and second electrodes are the same, and each of the bonded first and second electrodes comprises a plurality of punctate electrodes or a plurality of strip-shaped electrodes.

5. The solid-state light-emitting device as claimed in claim 1, wherein each of the bonded first and second electrodes comprises a strip-shaped electrode group, and the strip-shaped electrode group of the first electrode is perpendicular with the strip-shaped electrode group of the second electrode to form a vertical grid connection of the bonded first and second electrodes.

6. The solid-state light-emitting device as claimed in claim 1, wherein a gap is defined between every adjacent two light-emitting components due to thicknesses of the first electrode and the second electrode, and a transparent material is filled in the gap.

7. The solid-state light-emitting device as claimed in claim 1, wherein the plurality of light-emitting components are a plurality of light-emitting components with same colors.

8. The solid-state light-emitting device as claimed in claim 1, wherein the plurality of light-emitting components are a plurality of light-emitting components with different colors.

9. The solid-state light-emitting device as claimed in claim 1, wherein each light-emitting component is a micro light-emitting diode (micro-LED) chip, the source layer is a multi-quantum well layer, and a length, a width, and a height of the micro-LED chip are all less than 100 μm.

10. The solid-state light-emitting device as claimed in claim 6, wherein a refractive index of the transparent material is in a range from 1.4 to 1.6.

11. A display device, comprising:
a driving substrate; and
a plurality of display pixels, disposed on the driving substrate and electrically connected to the driving substrate;
wherein each display pixel comprises a plurality of sub-pixels with different colors, and each sub-pixel utilizes the solid-state light-emitting device as claimed in claim 1.

12. The display device as claimed in claim 11, wherein the driving substrate is a passive matrix driving substrate or an active matrix driving substrate.

13. The display device as claimed in claim 11, wherein the first electrode of the light-emitting component disposed at a bottom of the stacked light-emitting structure in the vertical direction comprises a planar metal electrode; and the second electrode of the light-emitting component disposed at a top of the stacked light-emitting structure in the vertical direction comprises a plurality of punctate electrodes.

14. The display device as claimed in claim 11, wherein the first electrode of the light-emitting component disposed at a bottom of the stacked light-emitting structure in the vertical direction comprises a planar metal electrode; and the second electrode of the light-emitting component disposed at a top of the stacked light-emitting structure in the vertical direction comprises a planar transparent electrode.

15. A production method of a solid-state light-emitting device, comprising:
providing a plurality of first light-emitting components spaced apart from each other and disposed on a transition carrier plate, wherein each first light-emitting component comprises a first electrode, a second electrode, a first semiconductor layer, a source layer and a second semiconductor layer; and the first semiconductor layer, the source layer and the second semiconductor layer are sequentially stacked between the first electrode and the second electrode in a vertical direction, the first electrode is disposed on a side of the first semiconductor layer facing away from the source layer, and the second electrode is disposed on a side of the second semiconductor layer facing away from the source layer;
providing a plurality of light-emitting structures spaced apart from each other and disposed on a growth substrate, wherein each light-emitting structure comprises a third electrode, a third semiconductor layer, a second source layer and a fourth semiconductor layer sequentially stacked in that order, and the growth substrate is disposed on a side of the fourth semiconductor layer facing away from the second source layer;
bonding the third electrodes of the plurality of light-emitting structures with the second electrodes of the plurality of first light-emitting components by utilizing a face-to-face bonding to obtain a plurality of stacked structures spaced apart from each other and disposed between the transition carrier plate and the growth substrate, wherein each stacked structure comprises a corresponding one of the plurality of first light-emitting components and a corresponding one of the plurality of light-emitting structures;
removing the growth substrate to expose the plurality of stacked structures spaced apart from each other; and
providing a fourth electrode on the side of the fourth semiconductor layer facing away from the second source layer of each stacked structure after the exposing to obtain a plurality of stacked light-emitting structures spaced apart from each other and disposed on the transition carrier plate, thereby forming a plurality of stacked light-emitting devices spaced apart from each other and disposed on the transition carrier plate; wherein each stacked light-emitting structure comprises a corresponding one of the plurality of first light-emitting components, and a second light-emitting component; and the second light-emitting component comprises a corresponding one of the plurality of light-emitting structures, and the fourth electrode.

16. The production method of the solid-state light-emitting device as claimed in claim 15, wherein the face-to-face bonding is utilized a metal bonding process.

17. The production method of the solid-state light-emitting device as claimed in claim 15, wherein a shape of the third electrode is consistent with a shape of the second electrode, and the third electrode and the second electrode each comprise a plurality of punctate electrodes or a plurality of strip-shaped electrodes.

18. The production method of the solid-state light-emitting device as claimed in claim 15, wherein each of the third electrode and the second electrode comprises a strip-shaped electrode group, and the strip-shaped electrode group of the third electrode is perpendicular with the strip-shaped electrode group of the second electrode to form a vertical grid connection.

19. The production method of the solid-state light-emitting device as claimed in claim 15, wherein the first light-emitting component and the second light-emitting component of each stacked light-emitting structure are light-emitting components with same colors.

20. The production method of the solid-state light-emitting device as claimed in claim 15, wherein the first light-emitting component and the second light-emitting component of each stacked light-emitting structure are light-emitting components with different colors.
